(19) United States
(12) Patent Application Publication
(10) Pub. No.: US 2010/0321106 A1
(43) Pub. Date: Dec. 23, 2010

(54) AMPLIFIER

(76) Inventors: Yen-Wei Hsu, Taipei (TW); Whei-Chyou Wu, Fremont, CA (US)

Correspondence Address: Yen-Wei Hsu, 7F No. 58, Jhouzih St.,Neihu District, Taipei, omitted

(21) Appl. No.: 12/489,447

(22) Filed: Jun. 23, 2009

(51) Int. Cl. H03F 9/00; G01R 33/34

(52) U.S. Cl. 330/63; 324/318

(57) ABSTRACT

This invention relates to an amplifier, especially an amplifier having electrical and magnetic input excitations.

### FIELD OF INVENTION

This invention relates to an amplifier, especially a passive amplifier, which can extract energy from a frequency-modulated static magnetic field into electrical power.

### BACKGROUND INFORMATION

The background information includes nuclear magnetic resonance section and hysteresis section. Both sections include some necessary mathematical models helpful to found our invention.

### Nuclear Magnetic Resonance

Referred to [9, Chapter 11-16], [1, Chapter 2], [4, Chapter 1], [16], [14], [5], [6, Chapter 3], [7, Page 135], [11, Chapter 1-5], [15, Chapter 7], [2] and [13], the Bloch equations, in general, which can be obtained as the following form of

$$\begin{matrix}\frac{d {M}_{x}}{d t} = γ ( {B}_{0} {M}_{y} - {M}_{z} {B}_{1} sin ω t ) - \frac{{M}_{x}}{{T}_{2}} & ( 1 ) \\ \frac{d {M}_{y}}{d t} = γ ( - {B}_{0} {M}_{x} + {M}_{z} {B}_{1} cos ω t ) - \frac{{M}_{y}}{{T}_{2}} & ( 2 ) \\ \frac{d {M}_{z}}{d t} = γ ( {B}_{1} {M}_{x} sin ω t + {M}_{y} {B}_{1} cos ω t ) - \frac{( {M}_{z} - {M}_{0} )}{{T}_{1}} & ( 3 )\end{matrix}$$

where (1), (2) and (3) are called “Bloch equations”, the term γ is called the magnetogyric ratio, B is any magnetic field such as a static magnetic field B₀ or a rotating field B₁. The T₁ and T₂ are called the longitudinal and transverse relaxation time respectively. Further, the simplest form of Bloch equations can be obtained as given the new variables in a complex number as the following,

M_{xy}=Mₓ+jM_{y} (4)

and

B_{xy}=Bₓ+jB_{y}

where j=\sqrt{√−1} then (1), (2) and (3) become in the complex form

$$\begin{matrix}\frac{d {M}_{xy}}{d t} = - j γ ( {B}_{z} {M}_{xy} - {M}_{z} {B}_{xy} ) - \frac{{M}_{xy}}{{T}_{2}} & ( 5 ) \\ \frac{d {M}_{z}}{d t} = j γ ( {\overline{B}}_{xy} {M}_{xy} - {\overline{M}}_{xy} {B}_{xy} ) - \frac{( {M}_{z} - {M}_{0} )}{{T}_{1}} & ( 6 )\end{matrix}$$

where M_{xy} is sometimes called transverse nuclear magnetization and their conjugated complex numbers are defined as

M̅_{xy}=Mₓ−jM_{y}

and

B̅_{xy}=Bₓ−jB_{y}

respectively. Given the initial conditions are at t=0 the transverse nuclear magnetization M_{xy}(0) experiences a constant magnetic flux density Bₐ=(0, 0, B₀), B₀>0, B₁=0, and T₁, T₂→∞, then (5) and (6) are simplified

$$\frac{d {M}_{xy}}{d t} = - j γ {M}_{xy} {B}_{0}$$

$$and$$

$$\frac{d {M}_{z}}{d t} = 0$$

of which solutions are the transverse nuclear magnetization M_{xy}

M_{xy}=M_{xy}(0)e^{-j(γB}^{₀}^{)t} (7)

and a constant magnetization in z-direction as

M_{z}=M₀

respectively. Thus (7) can be further expressed as the form of

M_{xy}=M_{xy}(0)(cos(ω₀t)−j sin(ω₀t)) (8)

where the value of ω₀ is defined as the form of

ω₀=γB₀ (9)

Comparing (4) to (8), the Mₓ and M_{y} are obtained

Mₓ=M_{xy}(0)cos(ω₀t) (10)

and

M_{y}=−M_{xy}(0)sin(ω₀t) (11)

respectively.

Following the previous simplification settings and the relaxization time conditions are some bounded constants, let (1), (2) and (3) under an applied static field Bₐ=B₀e_{z} and with a constant M_{z}=M₀, be obtained as

$$\begin{matrix}\frac{d {M}_{x}}{d t} = γ {B}_{0} {M}_{y} - \frac{{M}_{x}}{{T}_{2}} & ( 12 ) \\ \frac{d {M}_{y}}{d t} = - γ {B}_{0} {M}_{x} - \frac{{M}_{y}}{{T}_{2}} & ( 13 ) \\ \frac{d {M}_{z}}{d t} = 0 & ( 14 )\end{matrix}$$

If a nucleus imparts a magnetic moment μ and an angular momentum I, these are paralleled, ie.,

μ=γI

where

$$ℏ = \frac{h}{2 π}$$

h is Planck's constant. Let the (10) and (11) be the forms of

Mₓ=M₀e^{-(t/T}^{₂}⁾cos ω₀t (15)

and

M_{y}=−M₀e^{-(t/T}^{₂}⁾sin ω₀t (16)

respectively, then substitution of (12) and (13), the free precession frequency (9) can further define the “Larmor frequency” ω₀ also (9) is called “Larmor equation”. Moreover, we can change the order of B₀ from right to left side of equation (9) as

$${B}_{0} = \frac{{ω}_{0}}{γ} \qquad ( 17 )$$

That means one static magnetic field B₀ is modulated by this specific frequency ω₀ as the following form

B₀→B₀(ω₀) (18)

Again, considering the an applied static magnetic field B₀, an applied rotationing field B₁ and a constant M_{z}=M₀, the T₁ and T₂ are some bounded constants case, (1), (2) and (3) become the forms of

$$\begin{matrix}\frac{d {M}_{x}}{d t} = γ ( {B}_{0} {M}_{y} - {M}_{0} {B}_{1} sin ω t ) - \frac{{M}_{x}}{{T}_{2}} & ( 19 ) \\ \frac{d {M}_{y}}{d t} = γ ( - {B}_{0} {M}_{x} + {M}_{0} {B}_{1} cos ω t ) - \frac{{M}_{y}}{{T}_{2}} & ( 20 ) \\ \frac{d {M}_{z}}{d t} = 0 & ( 21 )\end{matrix}$$

Also their corresponding solutions of (19), (20) are obtained by combining the (15), (16) and their particular solutions as the following

Mₓ=M₀e^{-t/T}^{₂} cos ω₀t +M₀A(B₀, B₁, γ,ω)cos ωt (22)

M_{y}=−M₀e^{-t/T}^{₂} sin ω₀t+M₀A(B₀, B₁, γ, ω) sin ωt (23)

where

A(B₀, B₁, γ, ω)>0

For the maximizing value of |M_{y}| in (22), its total amplitude of (22) is

$$\vert {M}_{y} \vert = {M}_{0} ( {e}^{- ( \frac{2 π}{γ {B}_{0} {T}_{2}} )} + A ( {B}_{0} , {B}_{1} , γ , ω ) )$$

Also its amplification gain which is the ratio of a static magnetic field B₀ and a dynamic field B₁ to a dynamic field B₁ is

$$G = \frac{{e}^{- ( \frac{2 π}{γ {B}_{0} {T}_{2}} )} + A ( {B}_{0} , {B}_{1} , γ , ω )}{A ( {B}_{0} , {B}_{1} , γ , ω )} > 1 \qquad ( 24 )$$

Hysteresis

Referred to [4, Chapter 1], [8, Chapter 8], [10, Page 325-327], [12, Chapter 1], [3, Chapter IV], [6, Page 261-274], the magnetic response of a media can be obtained as the following

B=μH (25)

where H and B and μ are magnetic intensity (Ampère/m), magnetic flux density (Weber/m², Tesla) and permeability

$$( \frac{( Weber \text{/} {m}^{2} )}{( Ampère \text{/} m )} = \frac{Weber}{Ampère - m} = \frac{Henry}{m} )$$

of the magnetic material respectively. In addition, if applying to a transformer, its permeability μ depends on the specific gap size between internal transformer cores and μ is not a constant. Furthermore, the power is defined by

$$\begin{matrix}\frac{d W}{d t} = I ( N \frac{d Φ}{d t} ) \\ = SNI \frac{d B}{d t}\end{matrix} \qquad ( 26 )$$

and changing the variable from I to H which represents a magnetic intensity which has N turns and carries a current I through the length l core,

$$H = ( \frac{N}{l} ) I$$

then (26) becomes the form of

$$\begin{matrix}\frac{d W}{d t} = ( Sl ) ( \frac{N}{l} ) I \frac{d B}{d t} \\ = τ H \frac{d B}{d t}\end{matrix} \qquad ( 27 )$$

where the S, N are the cross-section area and number of turns respectively, the volume T of the magnetic core of which the length is l, is defined by

ρ=Sl

and the magnetic induction B is

$$B = \frac{Φ}{S}$$

where Φ is the magnetic flux. Taking the integral to (27), the total energy of the magnetic core during one cycle around the hysteresis loop is obtained as

$$W = τ ∮ HdB \qquad ( 28 )$$

For delivering the maximizing energy (28) in this core, i.e.,

$${W}_{max} = Max ( τ ∮ HdB ) \qquad ( 29 )$$

As the B reaches to the Bₘₐₓ in the hysteresis loop, which means this magnetic core is saturated. That is,

B=Bₘₐₓ (30)

and

H=Hₘₐₓ

which means the hysteresis curve becomes a closed rectangular loop and the maximized total energy (29) in the volume τ core is

Wₘₐₓ=τBₘₐₓHₘₐₓ (31)

This is a saturable reactor. Furthermore, substituting (25) into the (31), the work-done is then obtained as

$$\begin{matrix}{W}_{max} = \frac{τ}{μ} {B}_{max}^{2} \\ = μ τ {H}_{max}^{2}\end{matrix}$$

in the square-loop of hysteresis.

As a result, the B₀ in (24) is replaced by (30),

$$G = \frac{{e}^{- ( \frac{2 π}{γ {B}_{max} {T}_{2}} )} + A ( {B}_{0} , {B}_{1} , γ , ω )}{A ( {B}_{0} , {B}_{1} , γ , ω )}$$

the maximal value of the term e⁻(2π/γB₀T₂) is near to one,

$$0 < {e}^{- ( \frac{2 π}{γ {B}_{max} {T}_{2}} )} = {Max}_{arg ( {B}_{0} )} ( {e}^{- ( \frac{2 π}{γ {B}_{0} {T}_{2}} )} ) \leq 1$$

where the B₀ is a bounded value for the common usages magnetic materials. In other word, the maximizing gain in (24) is obtained under given the bounded static magnetic flux density (30).

### REFERENCES

[1] Edwin D. Becker. High Resolution NMR: Theory and Chemical Applications. Academic Press, http://www.apnet.com, 3rd edition, 1999.

[2] Felix Bloch. The principle of nuclear induction, 1952.

[3] Fred Alan Fish. Fundamental Principles of Electric and Magnetic Circuits. BiblioBazaar, LLC, http://www.bibliobazaar.com/opensource, 2008.

[4] Alberto Passos Guimaraes and I. S. Oliveira. Magnetism and Magnetic Resonance in Solids. A John Wiley and Sun, Inc., http://www.wiley.com, 1998.

[5] Arthur R. Von Hippel. Dielectrics and Waves. A John Wiley & Sun, Inc., http://www.wiley.com, 1954.

[6] Arthur Von Hippel. Dielectric Materials and Applications. Artech House Publishers., http://www.artechhouse.com, 1995.

[7] John David Jackson. Classical Electrodynamics. John Wiley & Sun, Inc., http://www.wiley.com, 2nd edition, 1962.

[8] H. W. Katz. Solid State Magnetic and Dielectric Devices. A John Wiley & Sun, Inc., http://www.wiley.com, 1959.

[9] Charles Kittel. Introduction to Solid State Physics. John Wiley & Suns, Inc., http://as.wiley.com/, 8th edition, 2004.

[10] Paul Lorrain and Dale R. Corson. Electromagnetic Fields and Waves. W. H. Freeman and Company, 2nd edition, 1970.

[11] Robert C. O'Handley. Modern Magnetic Materials: Principles and Applications. John Wiley & Sun, Inc., http://www.wiley.com, 1999.

[12] Sophocles J. Orfanidis. Eletromagnetic Waves and Antennas. Rutgers University., http://www.ece.rutgers.edu/orfanidi/ewa/, 2004.

[13] E. M. Purcell. Research in nuclear magnetism, 1952.

[14] Edward M. Purcell. Berkeley Physics Course: Electricity and Magnetism., volume 2. McGraw-Hill Science, Engineering, Math., http://www.cambridge.org, 2nd edition, 1984.

[15] Pavel Ripka. Magnetic Sensors and Magnetometers (Artech House Remote Sensing Library). Artech House Publishers, http://www.artechhouse.com, 2001.

[16] Charles P. Slichter. Principles of Magnetic Resonance (Springer Series in Solid-State Sciences) (v. 1). Springer, http://www.springer.com, 3rd edition, 1996.

### SUMMARY OF THE INVENTION

It is a first objective of the present invention to provide an amplifier which can extract energy from a static magnetic field into electrical power.

It is a second objective of the present invention to provide a device for frequency-modulating a static magnetic field.

It is a third objective of the present invention to provide a power conversion circuit by employing the amplifier.

It is a fourth objective of the present invention to provide an assembly using the Lenz current as ac input excitation to the amplifier.

It is a fourth objective of the present invention to provide a Lenz circuit to drive electrical current alternately through the amplifier.

It is a fifth objective of the present invention to provide a switching circuit to drive electrical current alternately or frequency-modulated dc through the amplifier.

It is a sixth objective of the present invention to provide an electrical power pumping device.

### BRIEF DESCRIPTION OF THE DRAWINGS

FIG. 1a has shown the nuclear magnetic resonance experiment;

FIG. 1b has shown an embodiment of an amplifier;

FIG. 1c has shown another amplifier;

FIG. 1d has shown an amplifier including three output magnetic conductors coupled in parallel with an input magnetic conductor;

FIG. 1e has shown a transformer;

FIG. 2 has shown an amplifier including four output magnetic conductors coupled in parallel with an input magnetic conductor;

FIG. 3 has shown two amplifiers coupled in series;

FIG. 4a has shown an assembly with a dc source;

FIG. 4b has shown an assembly with an ac source;

FIG. 4c has an shown a wide-band damper added to the assembly of FIG. 4b;

FIG. 5a has shown the structure of a typical power transformer installed at end-user site;

FIG. 5b has shown an electrical power pumping device;

FIG. 6a has shown an input and output magnetic conductors have a shape of rectangular cuboid;

FIG. 6b is the front view of the conductor of FIG. 6a;

FIG. 7a has shown an input and output magnetic conductors have a shape of cylinder; and

FIG. 7b is the front view of the conductor of FIG. 7a.

### DETAILED DESCRIPTION OF THE INVENTION

The Bloch equations were first introduced in the content of nuclear magnetic resonance or NMR in short, where they give the evolution of a spin (elementary magnetic moment) in a combined static magnetic field along the z axis and an ac field in the x-y plane. In the experiment an ac magnetic field is usually applied along the x or y axis and the static magnetic field of a static magnet is applied along the z axis. The x, y and z axises are perpendicular with each other. The magnetic resonance experiment having electrical and magnetic input excitations interests the behavior of the magnetization in the two combined input excitations.

The well known Bloch equations (1), (2) and (3) derived for NMR can be found in the nuclear magnetic resonance section of the background information of the present invention. B₀ is a magnetic field constant in time such as a static magnetic field, and B₁is a magnetic field dependent on time such as a rotating magnetic field or an ac induced magnetic field. The Mₓ, M_{y} and M_{z} shown in the Bloch equations are respectively the magnetization along the x, y and z axises. The equations (1), (2) and (3) can be further reduced to the equations (19), (20) and (21) with a static magnetic excitation Bₐ=B₀e_{z} applied along the z axis and with a constant M_{z}=M₀. It's noticed that the structural matrix of the two equations (19) and (20) is in canonical form, which means that the two equations (19) and (20) will oscillate in resonance.

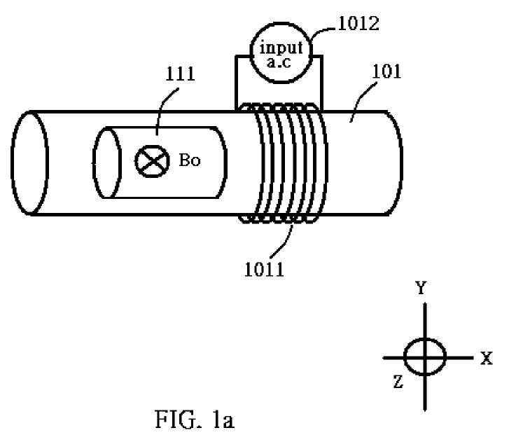

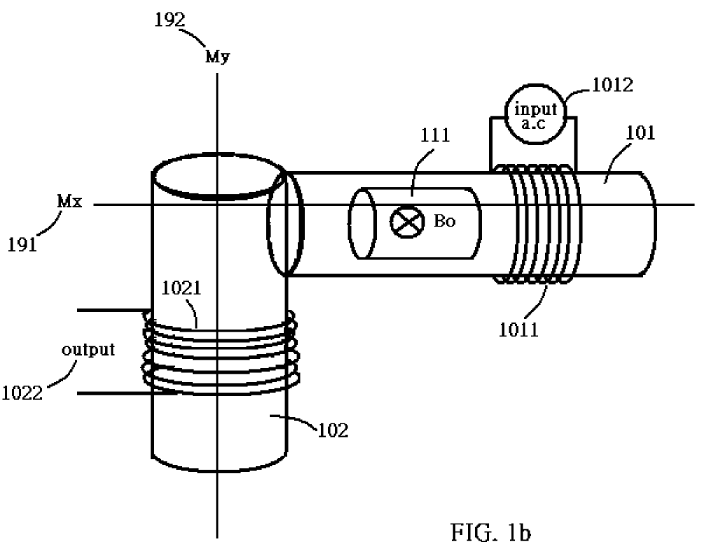

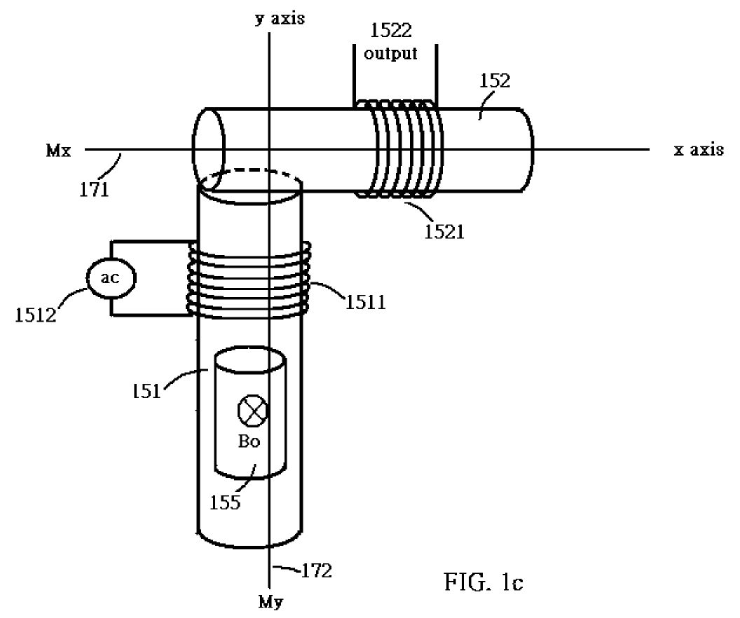

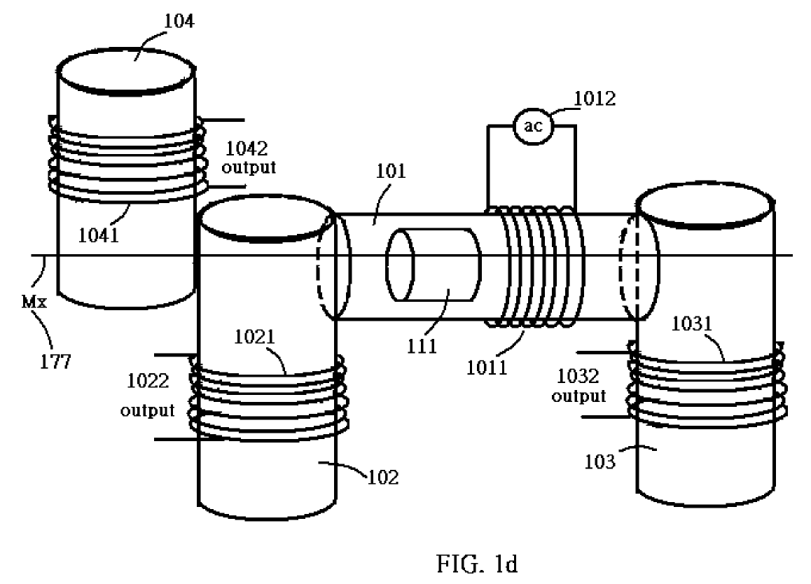

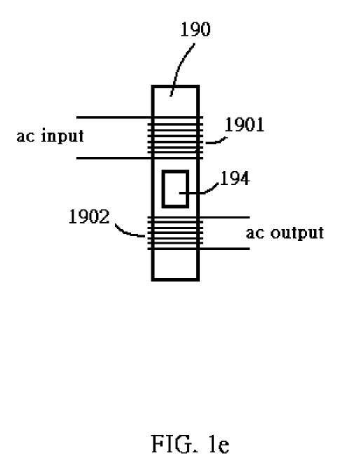

FIG. 1a has shown the nuclear magnetic resonance experiment including a specimen 101 disposed with its magnetization along the x axis, an input conductive coil 1011 winding around the specimen 101 for receiving input excitation which can be ac or frequency-modulated dc, and a static magnet 111 disposed with its static magnetic field along the z axis and disposed within a magnetically interactive distance adjacent to the specimen 101.

With the static magnetic excitation Bₐ=B₀e_{z} applied along the z axis and with a constant M_{z}=M₀, the equations (1), (2) and (3) are respectively reduced to the equations (19), (20) and (21). It's noticed that two equations (19), (20) are in the form of resonance mode and their solutions Mₓ and M_{y} have been respectively shown by the equations (22) and (23).

The experiment of FIG. 1a was for detecting the characteristics of the specimen 101 but didn't further explain what happens to the M_{y} such as how to realize the M_{y} and the relation between the Mₓ and M_{y}. The famous magnetic resonance experiment (NMR) of FIG. 1a and the Bloch equations described for the NMR are the bases to the present invention. From the two equations (19), (20), it's noticed that the M_{y} and Mₓ come as a pair and will oscillate in resonance. The term “oscillate in resonance” implies duality. One oscillates in resonance with another. The M_{y} or Mₓ can not oscillate in resonance without the other one because one can not oscillate in resonance by itself. So, another magnetic conductor with its magnetization along the y axis is needed for realizing the M_{y}. And, further, electrical output can be obtained at a conductive coil winding around the magnetic conductor of M_{y}.

For example, the nuclear magnetic resonance experiment shown in FIG. 1a has shown the only specimen 101 with its magnization along the x axis and the input excitation and output signal go through the same coil 1011 winding around the specimen 101. The NMR of FIG. 1a doesn't show any magnetic conductor to realize the M_{y}. This explains why the output signal detected from the coil 1011 is so tiny for no significant amplification because no oscillation occurs.

Another example, FIG. 1e has shown a magnetic conductor 190 disposed with its magnetization along the y axis, a first coil 1901 for receiving ac input excitation winding around the magnetic conductor 190, a second coil 1902 for output winding around the magnetic conductor 190 and a static magnet 194 disposed adjacent to the magnetic conductor 190. FIG. 1e doesn't show any magnetic conductor to realize the Mₓ. This explains why the electrical output of the second coil 1902 has no significant amplification because no oscillation happens. The device of FIG. 1e is just a transformer.

It's noticed that the terms M₀B₁ sin ωₜ and M₀B₁ cos ωₜ respectively in the equations (19) and (20) become forcing terms which are irrelevant to the states variables Mₓ, M_{y}. Equations (22) and (23) are the solutions to the equations (19) and (20). Taking the forcing terms M₀B₁ sin ωₜ and M₀B₁ cos ωₜ respectively out of the equations (19) and (20) leaves the homogeneous terms shown by equations (12) and (13) resulting in obtaining the equation (17), which has explicitly revealed that the static magnetic field is frequency-modulated by the specific frequency ω₀, or in other words, the static magnetic field is a function of frequency explicitly revealed by the equation (18). From the point of view of this interpretation, the present invention has also revealed an inventive device to frequency-modulated a static magnetic field. The amplification gain shown by the equation (24) is larger than 1, which proves the amplification. The term e^{-(2/π/γB}^{₀}_{T}^{₂}⁾ appeared in the equation (24) of amplication gain is between 0 and 1, so that if the frequency ω of the ac input excitation is one order larger than the value of denominator the amplication gain can be possibly close to 2, almost doubles the input. For the convenience of explanation, if a conductive coil winds around a magnetic conductor for providing electrical output then the conductive coil can be called output conductive coil and the magnetic conductor wound by the output conductive coil can be called output magnetic conductor in the present invention. If a conductive coil winds around a magnetic conductor for receiving input excitation the conductive coil can be called input conductive coil and the magnetic conductor wound by the input conductive coil can be called input magnetic conductor in the present invention.

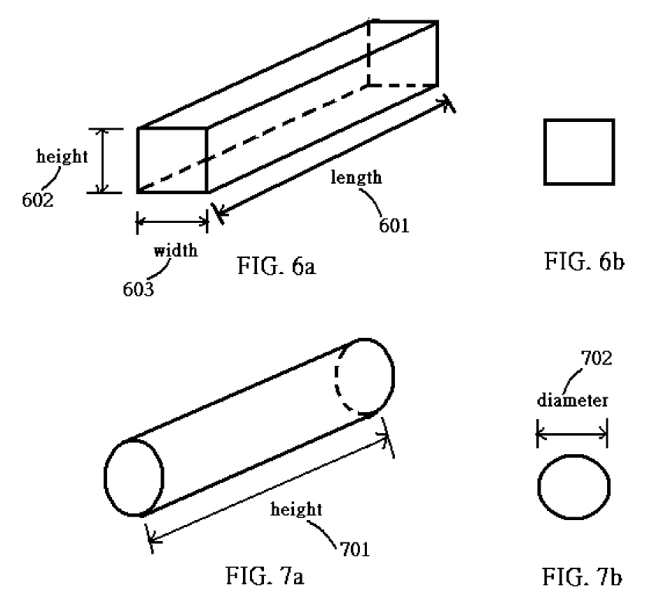

The term “magnetic conductor” used in the present invention means a device can deliver significant magnetic energy effectively. The shapes of the input and output magnetic conductors are not limited in the invention. The geometric structures of the input and output magnetic conductors are not limited in the invention. The materials made of the input and output magnetic conductors are not limited in the invention. The dimensions and sizes of the input and output magnetic conductors are not limited in the invention. For example, an input and output magnetic conductors can have a shape of a rectangular cuboid shown in FIG. 6a. FIG. 6b is the front view of the conductor of FIG. 6a. The magnetic conductor of FIG. 6 has a finite length 601 and can have the magnetization orientated along its length. The length 601, height 602 and width 603 of the magnetic conductor shown in FIG. 6 are not limited in the invention. For another example, a magnetic conductor can have a shape of a cylinder shown in FIG. 7a. FIG. 7b is the front view of the conductor of FIG. 7a. The magnetic conductor of FIG. 7 has a finite height 701 and can have the magnetization along its height orientation. The height 701 and diameter 702 of the cylindrical magnetic conductor shown in FIG. 7 are not limited in the invention. The cylindrical input and output magnetic conductors have been demonstrated in the present invention for some advantages: (1) the coils are easier wound around them and (2) they can be easier made with magnetization orientated along their height. The NMR of FIG. 1a will be employed to continue the revelation of the invention. The specimen 101 shown in FIG. 1a can also be called “input magnetic conductor” according to the definition above. Based on FIG. 1a, if a first output magnetic conductor is disposed with its magnetizaion along the y axis adjacent to the input magnetic conductor 101 of FIG. 1a, and at least a portion of the magnetization of the input magnetic conductor along the x axis magnetically intersect with at least a portion of the first output magnetic conductor then the magnetization M_{y} can be found on the first output magnetic conductor, and further, if a first output conductive coil is wound around the first output magnetic conductor then electrical output can be obtained at the first output conductive coil. The wavelength of magnetic field is very short so that any two magnetically interactive devices should be disposed as close as possible to gain the most magnetic interactions with each other. For example, the two magnetically interactive devices can be in physical contact with each other. FIG. 1b has shown the first output magnetic conductor 102 disposed with its megatization along the y axis in physical contact with the input magnetic conductor 101, the first output conductive coil 1021 winding around the first output magnetic conductor 102 and an electrical output 1022 obtained at the first output conductive coil 1021. Lines 191 and 192 respectively represent the Mₓ and M_{y} and it's noticed that the Mₓ line 191 intersects with at least a portion of the first output magnetic conductor 102.

The magnetization generated in the first output magnetic conductor 102 is the first output magnetic conductor 102 responding to the magnetization of the input magnetic conductor 101, which can be proved by the frequency responses found on the first output magnetic conductor different from that of the ac input excitation. FIG. 1b has shown that the input magnetic conductor 101 of FIG. 1b is disposed with its magnetization along the x axis so that the output magnetic conductor 102 is disposed with its magnetization along the y axis. On the contrary, if an input magnetic conductor is disposed with its magnetization along the y axis so that an output magnetic conductor is disposed with its magnetization along the x axis, which is shown in FIG. 1c. FIG. 1c has shown an input magnetic conductor 151 with its magnetization along the y axis, an input conductive coil 1511 winding around the input magnetic conductor 151 for receiving ac input excitation, a static magnet 155 disposed with its static magnetical field along the z axis adjacent the input magnetic conductor 151, an output magnetic conductor 152 disposed with its magnetization along the x axis adjacent the input magnetic conductor 151 and an output conductive coil 1521 winding around the output magnetic conductor 152 for electrical output. Lines 171 and 172 respectively represent the Mx and My. It's noticed that My line 172 intersects a portion of the output magnetic conductor 152. Again, it is noticed that the magnetizations respectively of the input and output magnetic conductors are in-plane and the static magnetic field is perpendicular to the plane. If the static magnetic field of the static magnet 111 are not along the z axis or/and the x and y axises are not perpendicular with each other, the equations (1), (2) and (3) can not be respectively reduced to the equations (19), (20) and (21) then the Mₓ, M_{y} and M_{z} exist and they might not oscillate in the resonant mode with each other so that the output magnetic conductor is more difficult to be precisely located for the maximum magnetic power transferred among them. In this case the amplification might exist but is limited. Even so, the present invention is not limited to the embodiment of FIG. 1b of which the x, y and z axises are perpendicular with each other and the static magnetic field is along the z axis with constant magnetization. A plurality of the output magnetic conductors can be coupled in parallel with an input magnetic conductor.

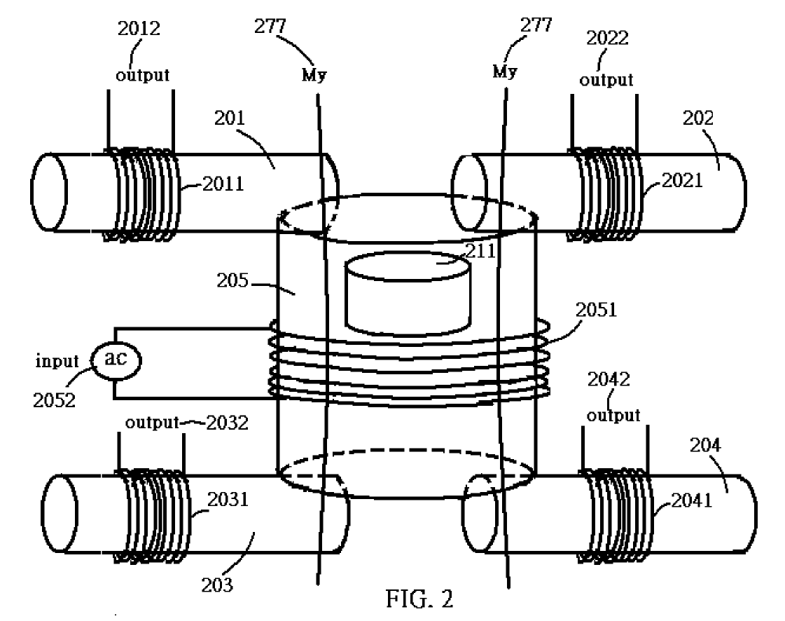

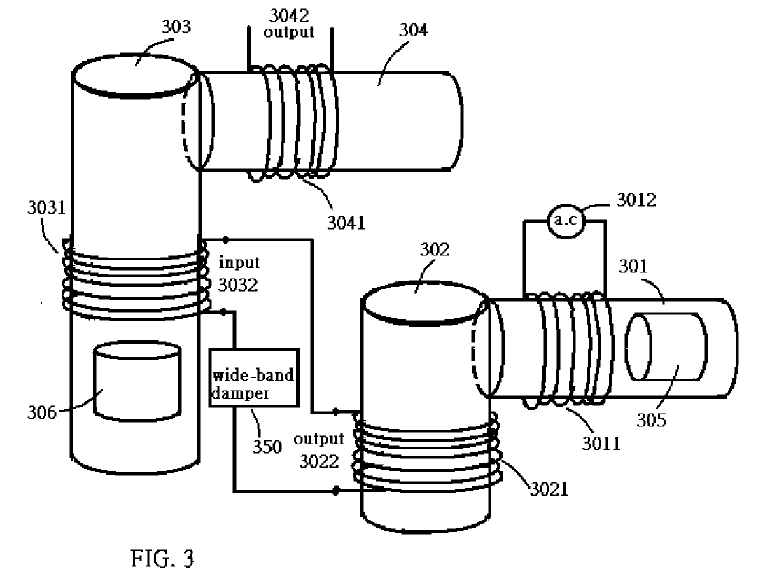

An example by using FIG. 1b and shown in FIG. 1d, a second output magnetic conductor 103 can be disposed with its magnetization along the y axis in physical contact with the other end of the input magnetic connector 101, and a third output magnetic conductor 104 is disposed with its magnetization along the y axis in physical contact with the first output magnetic conductor 102. At least a portion of the magnetization of the input magnetic conductor 101 flow through or magnetically intersect with at least a portion of the second and third output magnetic conductor 103, 104. A line 177 shown in FIG. 1d expresses that the Mx of the input magnetic conductor 101 magnetically intersects the three output magnetic conductors 102, 103 and 104. Electrical power can be obtained at each of the three output conductive coils 1021, 1031 and 1041 respectively winding around the three output magnetic conductors 102, 103 and 104. While the example of FIG. 1d shows three output magnetic conductors coupled in parallel with an input magnetic conductor it is understood that the principles described above can be applied to more output magnetic conductors coupled in parallel with an input magnetic conductor. The total gain is the summation of each gain of all the output magnetic conductors coupled in parallel. FIG. 1d has shown only one output magnetic conductor couples with each end of the input magnetic conductor 101. An embodiment of FIG. 2 has shown more than one output magnetic conductor are disposed in contact with an end of an input magnetic conductor. FIG. 2 has shown four output magnetic conductors 201, 202, 203 and 204 with their magnetizations along the x axis coupled in parallel with an input magnetic conductor 205 with its magnetization along the y axis. The two output magnetic conductors 201, 202 are in physical contact with an end of the input magnetic conductor 205 and the other two output magnetic conductors 203, 204 are in physical contact with the other side of the input magnetic conductor 205. Two lines 277 express that at least a portion of magnetization of the input magnetic conductor 205 magnetically intersect with at least a portion of the four output magnetic conductors 201, 202, 203 and 204. Four electrical outputs 2012, 2022, 2032 and 2042 can be obtained respectively at the four output conductive coils 2011, 2021, 2031 and 2041 respectively winding around the four magnetic conductors 201, 202, 203 and 204. Two amplifiers can be coupled in series by electrically connecting an output conductive coil of a first amplifer with an input conductive coil of a second amplifer so that a closed loop connecting the two amplifiers will be formed by the out conductive coil and the input conductive coil electrically coupled in series. And, further, a wide-band damper can be electrically coupled in series with the two conductive coils in the closed loop for stabilizing the dynamic property in the closed loop. By using the amplifiers of FIG. 1b and 1c, FIG. 3 has shown the two amplifiers coupled in series. A first amplifier comprises a first input magnetic conductor 301 disposed with its magnetization along the x axis, a first input conductive coil 3011 winding around the first input magnetic conductor 301 for receiving ac input excitation 3012, a first static magnet 305 disposed with its static magnetic field along the z axis adjacent to the first input magnetic conductor 301, a first output magnetic conductor 302 disposed with its magnetization along the y axis in physical contact with the first input magnetic conductor 301 and a first output conductive coil 3021 winding around the first output magnetic conductor 302 for electrical output. A second amplifier comprises a second input magnetic conductor 303 disposed with its magnetization along the y axis, a second input conductive coil 3031 winding around the second input magnetic conductor 303, a second static magnet 306 disposed with its static magnetic field along the z axis adjacent to the second input magnetic conductor 303, a second output magnetic conductor 304 disposed with its magnetization along the x axis in physical contact with the second input magnetic conductor 303, and a second output conductive coil 3041 winding around the second output magnetic conductor 304 for electrical output. A closed loop connecting the two amplifiers is formed by the first output conductive coil 3021 and the second input conductive coil 3031 electrically connected in series. A wide-band damper 350 can be disposed into the closed loop and the wide-band damper 350, the first output conductive coil 3021 and the second input conductive coil 3031 are coupled in series with each other.

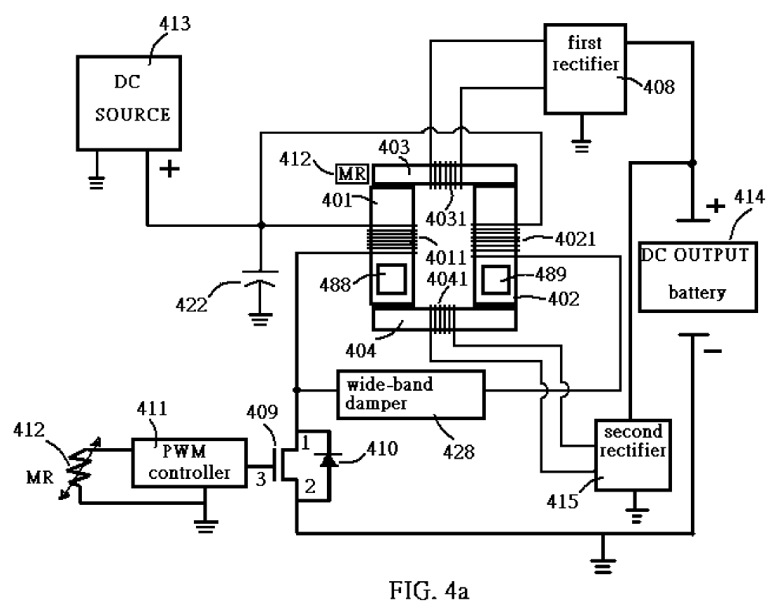

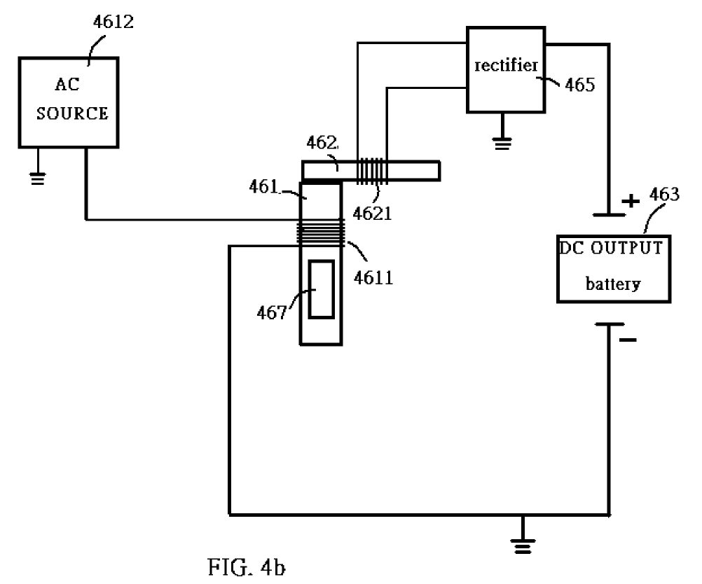

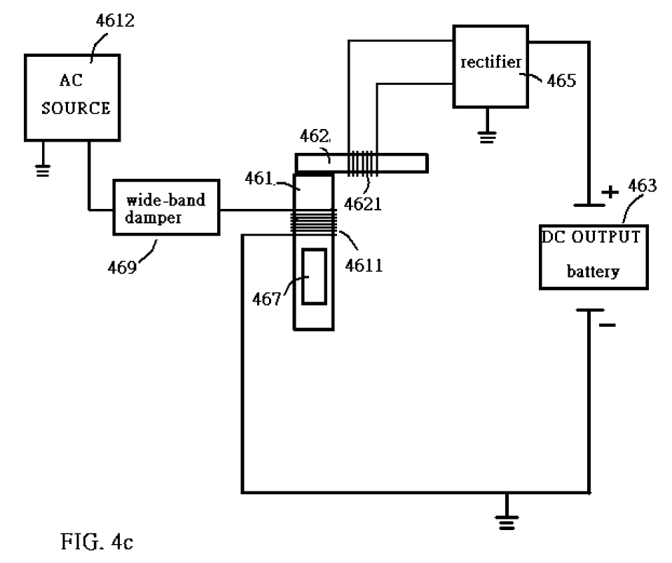

The wide-band damper 350 is for stabilizing the dynamic characterization of the loop connecting the two amplifiers. If the closed loop is dynamically stable then the damper 350 can be neglected. While the example of FIG. 3 has shown two amplifiers coupled in series it is understood that the principles described above can be applied to more amplifiers coupled in series. The total gain of a plurality of the amplifiers coupled in series is the multiplication of the gain of each amplifier. The total gain of a plurality of output magnetic conductors coupled in parallel with an input magnetic conductor is the summation of the gain of each output magnetic conductor with the input magnetic conductor. The ac Lenz current, eddy current or thermal electricity can be the ac current excitation to the present invention “amplifier”. A dc source such as battery is needed in every portable device. A switching circuit will usually come with the dc source for power conversion. The switching circuit will bring Lenz effect which can cause circuit unstable and waste a certain amount of power. The present invention will show a power conversion circuit by using Lenz current of Lenz effect as an input excitation to the amplifier to restore back some power. FIG. 4a and 4b have respectively shown an assembly powered by a dc and an ac source. The assembly shown in FIG. 4a comprises a dc source 413, a first amplifier, a second amplifer, a switching circuit, a Lenz circuit, a first rectifier 408, a second rectifier 415 and a high-pass filter 422. The switching circuit electrically connected with the dc source 413 drives electrical current alternately or frequency-modulated dc through a first input conductive coil of the first amplifier.

The load of the switching circuit, the Lenz circuit and the high-pass filter are electrically connected in parallel with each other. The returned Lenz current will flow from the switching circuit to the Lenz circuit which can stabilize the Lenz current and drive the stabilized Lenz current through a second input conductive coil of the second amplifier. The high-pass filter 422 is for leading the returned high frequency Lenz current to the ground against being feeding into the first input conductive coil 4011 of the first amplifier, and the high-pass filter 422 is also for filtering out unstable power from the dc source 413. The first and second rectifiers 408, 415 are for rectifying ac into dc which can be saved into battery. A first amplifier comprises a first input magnetic conductor 401 disposed with its magnetization along the y axis and having a first and second ends, a first input conductive coil 4011 winding around the first input magnetic conductor 401 for receiving input excitation, a first static magnet 488 disposed with its static magnetic field along the z axis and disposed within a magnetically interactive distance adjacent to the first input magnetic conductor 401, a first output magnetic conductor 403 disposed with its magnetization along the x axis adjacent to the first end of the first input magnetic conductors 401 and at least a portion of the magnetization of the first input magnetic conductor 401 magnetically intersecting with at least a portion of the first output magnetic conductor 403, a first output conductive coil 4031 winding around the first output magnetic conductor 403 for a first electrical output, a second output magnetic conductor 404 disposed with its magnetization along the x axis adjacent to the second end of the first input magnetic conductors 401 and at least a portion of the magnetization of the first input magnetic conductor 401 magnetically intersecting with at least a portion of the second output magnetic conductor 404, and a second output conductive coil 4041 winding around the second output magnetic conductor 404 for a second electrical output. A second amplifer comprises a second input magnetic conductor 402 disposed with its magnetization along the y axis and having a first and second ends, a second input conductive coil 4021 winding around the second input magnetic conductor 402 for receiving input excitation, a second static magnet 489 disposed with its static magnetic field along the z axis and disposed within a magnetically interactive distance adjacent to the second input magnetic conductor 402, the first output magnetic conductor 403 also disposed adjacent to the first end of the second input magnetic conductors 402 and at least a portion of the magnetization of the second input magnetic conductor 402 magnetically intersecting with at least a portion of the first output magnetic conductor 403, and the second output magnetic conductor 404 also disposed adjacent to the second end of the second input magnetic conductors 402 and at least a portion of the magnetization of the second input magnetic conductor 402 magnetically intersecting with at least a portion of the second output magnetic conductor 404. The embodiment of FIG. 4a has shown that the first and second input magnetic conductors respectively of the first and second amplifiers share the two output magnetic conductors 403, 404. The switching circuit comprises a dc source 413, a power transistor 409, a PWM controller 411 and the first input conductive coil 4011 of the first amplifier of which the dc source 413, the power transistor 409 and the first input conductive coil 4011 electrically coupled in series with each other. The power transistor 409 comprises a first, second and third terminals (marked by 1, 2 and 3 in FIG. 4a) of which the electrical connection and disconnection between the first and second terminals are controlled by signals received on the third terminal. The PWM controller 411 couples with the third terminal of the power transistor 409 for controlling the electrical connection and disconnection switchings between the first and second terminals of the power transistor 409. A magnetic resistor (MR) 412 couples with the PWM controller 411 and the magnetic resistor 412 is disposed within a magnetically interactive distance adjacent to at least one of the first and second output magnetic conductors 403, 404 for feeding the sensed magnetic intensities back to the PWM controller 411 to re-shape its output waveforms. The magnetic resistor 412 represents to include the tunnel magnetic resistor (TMR).

Lenz effect will be generated when the power transistor 409 is in off duty. The high frequency ac Lenz current in nature will flow from the cutting point of the power transistor 409 of the switching circuit back to the dc source 413. The returned high frequency ac Lenz current will be blocked by the firs t input conductive coil 4011 for high frequency excitation so that the Lenz circuit is there for bypassing the high frequency Lenz current. The Lenz circuit comprising a wide-band damper 428 and the second input conductive coil 4021 electrically connected in series is electrically connected in parallel with the load of the switching circuit. Obviously, the load of the switching circuit of FIG. 4a is the first input conductive coil 4011. The damper 428 comprises at least an ac/dc isolation device, for example, a capacitor or diode, which prohibits the dc current from the dc source 413 from flowing into the Lenz circuit and allows the ac Lenz current to flow through the Lenz current. The present invention is not limited any particular ac/dc isolation device. The damper 428 can perform the frequency-shifting and function to stabilize the dynamic Lenz current before being fed into the second input conductive coil 4021 of the second amplifier. A good wide-band damper is very important in many circuits, for example, it can function to stabilize the circuit against divergence, especially in an amplifier circuit. Further, the material made of the second input magnetic conductor 402 and the number of coil turns on the conductor 402 are also very important factors deciding the difficulty for Lenz current to pass the second input conductive coil 4021. The present invention is not limited to any particular wide-band damper. The present invention is not limited to any particular switching circuit. The present invention is not limited to any particular Lenz circuit. The embodiment of FIG. 4a has shown that the first and second amplifiers work at different phases. The first and second rectifiers 408, 415 respectively rectify the electrical outputs of the first and second output conductive coils 4031, 4041 into dc which can be saved into battery.

A plurality of output magnetic conductors can be coupled in parallel with the first and second input magnetic conductors 401, 402 respectively of the first and second amplifiers as revealed earlier by the embodiments of FIG. 1d and FIG. 2. At least an output conductive coil winds around each output magnetic conductor for electrical output which can be rectified into dc by a rectifier if needed. A plurality of amplifiers can be coupled in series respectively with the first and second amplifier as revealed by the embodiment of FIG. 3. The number of the output magnetic conductors electrically coupled in parallel with the input magnetic conductor are not limited. The number of the amplifiers respectively electrically coupled in series with the first and second amplifiers are not limited.

The first and second electrical outputs respectively taken at two output conductive coils 4031, 4041 are ac so that the assembly of FIG. 4a can be viewed as an ac alternator. Both the first and second rectifiers 408, 415 are for rectifying the ac out from the two output conductive coils 4031, 4041 into dc which can be saved into a battery so that the assembly of FIG. 4a can be viewed as a charger. If the dc source 413 of FIG. 4a is a solarcell the assembly of FIG. 4a is a solarcell power device. Overall speaking, the assembly of FIG. 4a can be viewed as a power conversion circuit.

FIG. 4b has shown an assembly powered by an ac source so that the switching circuit is not needed. FIG. 4b has shown an ac source 4612, an input magnetic conductor 461, an input conductive coil 4611 winding around the input magnetic conductor 461, an output magnetic conductor 462, an output conductive coil 4621 winding around the output magnetic conductor 462 and a rectifier 465 for rectifying the electrical output from the output conductive coil 4621 into dc which can charge a battery 463. If the ac source 4612 has chances to be unstable a wide-band damper can be used as shown in FIG. 4c.

A plurality of output magnetic conductors can be coupled in parallel with the input magnetic conductor 461 of FIG. 4b and 4c as earlier revealed by the embodiments of FIG. 1d and FIG. 2. At least an output conductive coil winds around each output magnetic conductor for electrical output which can be rectified into dc by a rectifier if needed. A plurality of amplifiers can be coupled in series with the amplifier of FIG. 4b as revealed by the embodiment of FIG. 3. The number of the output magnetic conductors electrically coupled in parallel with the input magnetic conductor are not limited. The number of the amplifiers electrically coupled in series with the amplifier of FIG. 4b and 4c are not limited.

The amplifier can be an electrical power pumping device for power recovery used in the power transmission system. It's well known that electrical power from power plant is delivered to end-user through a power transformer installed at end-user site.

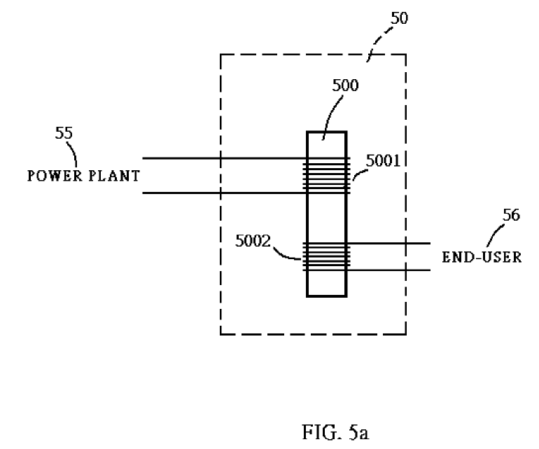

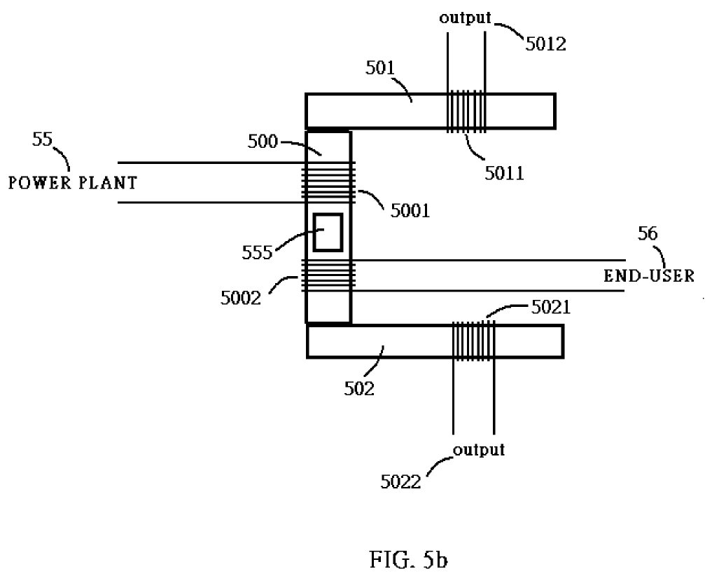

FIG. 5a has shown a typical power transformer 50 surrounded by a dotted block. The power transformer 50 includes an input magnetic conductor 500 with its magnetization along the y axis, a first conductive coil 5001 winding around the input magnetic conductor 500 for receiving ac from the power plant 55 and a second conductive coil 5002 winding around the input magnetic conductor 500 for electrical output of the end-user 56. The power from the power plant delivered to the end-user site suffers considerable loss both in the power transmission and the efficiency loss of the power transformer 50. For example, there are estimated 30% power loss in the transmission from power plant to the power transformer 50 at end-user site and 15% power loss on the power transformer so that only 60% of the power from power plant are really delivered to end user site. That's a very big power waste. The present invention “amplifier” can be used in the application as an electrical power pumping device to restore back considerable power.

FIG. 5b has shown a solution. Based on FIG. 5a, FIG. 5b has shown a first output magnetic conductor 501 disposed with its magnetization along the x axis and in physical contact with a first end of the input magnetic conductor 500, a first output conductive coil 5011 winding around the first output magnetic conductor 501 for a first electrical output, a second output magnetic conductor 502 disposed with its magnetization along the x axis and in physical contact with a second end of the input magnetic conductor 500, a second output conductive coil 5021 winding around the second output magnetic conductor 502 for a second electrical output and a static magnet 555 disposed with its magnetic field along the z axis adjacent to the input magnetic conductor 500. The electrical power from the power plant is ac input excitation to the first conductive coil 5001 and the first and second electrical outputs 5012, 5022 can be respectively taken at the first and second output conductive coils 5011, 5012. The outputs 5012 and 5022 have same phase so that they can be coupled in series or in parallel to modify output voltage or current level. It's noticed that induced power output at the second conductive coil 5002 of the transformer 50 is still available.

A plurality of output magnetic conductors can be coupled in parallel with the input magnetic conductor 500 of FIG. 5b as earlier revealed by the embodiments of FIG. 1d and FIG. 2, and each output magnetic conductor is wound with an output conductive coil for electrical output. Each ac electrical output from each output conductive coil can be followed by a rectifier to rectify the ac into dc if needed. A plurality of amplifiers can be electrically coupled in series with the amplifier of FIG. 5b as revealed by the embodiment of FIG. 3. The number of the output magnetic conductors electrically coupled in parallel with the input magnetic conductor are not limited. The number of the amplifiers electrically coupled in series with the amplifier of FIG. 5b are not limited.

1. An amplifier comprising:
a first input magnetic conductor disposed with its magnetization along a first axis;
a first input conductive coil winding around at least a portion of the first input magnetic conductor for receiving input excitation;
a first static magnet, disposed within a magnetically interactive distance adjacent to the first input magnetic conductor, disposed with its static magnetic field along a third axis;
a first output magnetic conductor disposed with its magnetization along a second axis adjacent to the first input magnetic conductor, wherein at least a portion of the magnetization of the first input magnetic conductor magnetically intersect with at least a portion of the first output magnetic conductor; and
a first output conductive coil winding around at least a portion of the first output magnetic conductor for electrical output.

2. The amplifier of claim 1, wherein the first input magnetic conductor and first output magnetic conductor have a shape of cylinders, and wherein the first, second and third axises are perpendicular with each other, and wherein the first output magnetic conductor is in physical contact with the first input magnetic conductor.

3. The amplifier of claim 2, further comprising:
a second output magnetic conductor; and
a second output conductive coil winding around at least a portion of the second output magnetic conductor for providing electrical output, wherein the second output magnetic conductor is disposed with its magnetization along the second axis adjacent to the first input magnetic conductor or the first output magnetic conductor, and at least a portion of the magnetization of the first input magnetic conductor magnetically intersect with at least a portion of the second output magnetic conductor.

4. The amplifier of claim 3, further comprising:
a second input magnetic conductor disposed with its magnetization along a fourth axis;
a second input conductive coil winding around at least a portion of the second input magnetic conductor, wherein the second input conductive coil and the first output conductive coil are electrically connected in series to form a closed loop.
a second static magnet, disposed within a magnetically interactive distance adjacent to the second input magnetic conductor, disposed with its static magnetic field along a sixth axis;
a third output magnetic conductor disposed with its magnetization along a fifth axis adjacent to the second input magnetic conductor, wherein at least a portion of the magnetization of the second input magnetic conductor magnetically intersect with at least a portion of the third output magnetic conductor; and
a third output conductive coil winding around at least a portion of the third output magnetic conductor for electrical output.

5. The amplifier of claim 4, wherein the fourth, the fifth axis and the sixth axises are respectively the first, second and third axises or the fourth, the fifth axis and the sixth axises are respectively the second, first and third axises.

6. The amplifier of claim 3, further comprising:
a second input magnetic conductor disposed with its magnetization along a fourth axis;
a second input conductive coil winding around at least a portion of the second input magnetic conductor;
a wide-band damper, wherein the wide-band damper, the second input magnetic conductor and the first output magnetic conductor are electrically connected in series with each other to form a closed loop;
a second static magnet, disposed within a magnetically interactive distance adjacent to the second input magnetic conductor, disposed with its static magnetic field along a sixth axis;
a third output magnetic conductor disposed with its magnetization along a fifth axis adjacent to the second input magnetic conductor, wherein at least a portion of the magnetization of the second input magnetic conductor magnetically intersect with at least a portion of the third output magnetic conductor; and
a third output conductive coil winding around at least a portion of the third output magnetic conductor for electrical output.

7. The amplifier of claim 6, wherein the fourth, the fifth axis and the sixth axises are respectively the first, second and third axises or the fourth, the fifth axis and the sixth axises are respectively the second, first and third axises.

8. An assembly, comprising:
a first input magnetic conductor disposed with its magnetization along a first axis;
a first input conductive coil winding around at least a portion of the first input magnetic conductor for receiving input excitation;
a first static magnet, disposed within a magnetically interactive distance adjacent to the first input magnetic conductor, disposed with its static magnetic field along a third axis;
a first output magnetic conductor disposed with its magnetization along a second axis adjacent to the first input magnetic conductor, wherein at least a portion of the magnetization of the first input magnetic conductor magnetically intersect with at least a portion of the first output magnetic conductor;
a first output conductive coil winding around at least a portion of the first output magnetic conductor for electrical output; and
a switching circuit driving electrical current alternately or frequency-modulated dc through the first input conductive coil.

9. The assembly of claim 8, wherein the switching circuit comprises a dc source, the first input conductive coil, a power transistor and a PWM controller, and the dc source, the first input conductive coil and the power transistor are electrically coupled in series with each other to form a closed loop, and the PWM controller is coupled with the power transistor to control the on and off switchings of the power transistor.

10. The assembly of claim 9, wherein the first input magnetic conductor and first output magnetic conductor have a shape of cylinders, and wherein the first, second and third axises are perpendicular with each other, and wherein the first output magnetic conductor is in physical contact with the first input magnetic conductor.

11. The assembly of claim 10, further comprising:
a second output magnetic conductor; and
a second output conductive coil winding around at least a portion of th e second output magnetic conductor for providing electrical output, wherein the second output magnetic conductor is disposed with its magnetization along the second axis adjacent to the first input magnetic conductor or the first output magnetic conductor, and at least a portion of the magnetization of the first input magnetic conductor magnetically intersect with at least a portion of the second output magnetic conductor.

12. The assembly of claim 11, further comprising:
a second input magnetic conductor disposed with its magnetization along a fourth axis;
a second input conductive coil winding around at least a portion of the second input magnetic conductor; wherein the second input conductive coil and the first output conductive coil are electrically coupled in series with each other to form a closed loop.
a second static magnet, disposed within a magnetically interactive distance adjacent to the second input magnetic conductor, disposed with its static magnetic field along a sixth axis;
a third output magnetic conductor disposed with its magnetization along a fifth axis adjacent to the second input magnetic conductor, wherein at least a portion of the magnetization of the second input magnetic conductor magnetically intersect with at least a portion of the third output magnetic conductor; and
a third output conductive coil winding around at least a portion of the third output magnetic conductor for electrical output.

13. The assembly of claim 12, wherein the fourth, fifth and the sixth axises are respectively the first, second and third axises or the fourth, fifth and the sixth axises are respectively the second, first and third axises.

14. The assembly of claim 11, further comprising:
a second input magnetic conductor disposed with its magnetization along a fourth axis;
a second input conductive coil winding around at least a portion of the second input magnetic conductor;
a wide-band damper, wherein the wide-band damper, the second input magnetic conductor and the first output magnetic conductor are electrically coupled in series with each other to form a closed loop;
a second static magnet, disposed within a magnetically interactive distance adjacent to the second input magnetic conductor, disposed with its static magnetic field along a sixth axis;
a third output magnetic conductor disposed with its magnetization along a fifth axis adjacent to the second input magnetic conductor, wherein at least a portion of the magnetization of the second input magnetic conductor magnetically intersect with at least a portion of the third output magnetic conductor; and
a third output conductive coil winding around at least a portion of the third output magnetic conductor for electrical output.

15. The assembly of claim 14, wherein the fourth, fifth and the sixth axises are respectively the first, second and third axises or the fourth, fifth and the sixth axises are respectively the second, first and third axises.

16. The amplifier of claim 15, further comprising:
a third input magnetic conductor disposed with its magnetization along a seventh axis;
a third input conductive coil winding around at least a portion of the third input magnetic conductor, having a first and second ends;
a third static magnet, disposed within a magnetically interactive distance adjacent to the third input magnetic conductor, disposed with its static magnetic field along a ninth axis;
a fourth output magnetic conductor disposed with its magnetization along a eighth axis adjacent to the second input magnetic conductor, wherein at least a portion of the magnetization of the third input magnetic conductor magnetically intersect with at least a portion of the fourth output magnetic conductor;
a fourth output conductive coil winding around at least a portion of the fourth output magnetic conductor for electrical output;
a Lenz circuit, electrically connecting in parallel with the load of the switching circuit, driving electrical current alternately through the third input conductive coil; and
a high-pass filter electrically connected in parallel with the switching circuit and the Lenz circuit.

17. The assembly of claim 16, wherein the seventh, eighth and the ninth axises are respectively the first, second and third axises or the seventh, eighth and the ninth axises are respectively the second, first and third axises, and wherein the Lenz circuit comprises a wideband damper and the second input conductive coil electrically connected in series, and the wide-band damper electrically connects with the switching circuit, and wherein the wide-band damper includes at least an ac/dc isolation device, which prohibits the dc current from the dc source from flowing into the Lenz circuit and allows the ac Lenz current to flow through the Lenz current.

18. The assembly of claim 17, further comprising:
a fifth output magnetic conductor; and
a fifth output conductive coil winding around at least a portion of the fifth output magnetic conductor for providing electrical output, wherein the fifth output magnetic conductor is disposed with its magnetization along the first or second axis adjacent to the third input magnetic conductor, or the fourth output magnetic conductor, and at least a portion of the magnetization of the third input magnetic conductor magnetically intersect with at least a portion of the fifth output magnetic conductor.

19. The assembly of claim 18, further comprising:
a fourth input magnetic conductor disposed with its magnetization along the first axis;
a fourth input conductive coil, comprising a first and second ends, winding around at least a portion of the fourth input magnetic conductor, wherein the first end of the fourth input conductive coil electrically connects the second terminal of the RLC wide-band damper and the second end of the fourth input conductive coil electrically connects the second end of the third, fourth and fifth output conductive coil;
a fourth static magnet, disposed within magnetically interactive distance adjacent to the fourth input magnetic conductor, disposed with its static magnetic field along the third axis;
a wide-band damper, wherein the wide-band damper, the fourth input magnetic conductor and the fourth or fifth output magnetic conductor are electrically coupled in series with each other to form a closed loop;
a sixth output magnetic conductor disposed with its magnetization along the second axis adjacent to the fourth input magnetic conductor, wherein at least a portion of the magnetization of the fourth input magnetic conductor magnetically intersect with at least a portion of the sixth output magnetic conductor; and
a sixth output conductive coil, comprising a first and second ends for providing electrical output, winding around at least a portion of the sixth output magnetic conductor.

20. The assembly of claim 19, further comprising a magnetic resistor (MR) coupled with the PWM controller for re-shaping the output waveforms of the PWM controller, wherein the magnetic resistor is disposed within a magnetically interactive distance adjacent to at least one of the first, second, third, fourth, fifth and sixth output magnetic conductors for feeding back the sensed magnetic intensity to the PWM controller to re-shape its output waveforms.

21. An assembly, comprising:
a first input magnetic conductor disposed with its magnetization along a first axis;
a first input conductive coil, having a first and second ends, winding around at least a portion of the first input magnetic conductor;
a first static magnet, disposed within magnetically interactive distance adjacent to the first input magnetic conductor, disposed with its static magnetic field along a third axis;
a first output magnetic conductor disposed with its magnetization along a second axis adjacent to the first input magnetic conductor, wherein at least a portion of the magnetization of the first input magnetic conductor magnetically intersect with at least a portion of the first output magnetic conductor;
a first output conductive coil, having a first and second ends for providing electrical output, winding around at least a portion of the first output magnetic, and
a power transmission line from power plant driving electrical current alternately through the first input conductive coil.

22. The assembly of claim 21, wherein the first, second and third axises are perpendicular with each other.

23. The assembly of claim 22, further comprising:
a second output magnetic conductor; and
a second output conductive coil winding around at least a portion of the second output magnetic conductor for providing electrical output, wherein the second output magnetic conductor is disposed with its magnetization along the second axis adjacent to the first input magnetic conductor, and at least a portion of the magnetization of the first input magnetic conductor magnetically intersect with at least a portion of the second output magnetic conductor.
